(19) United States
(12) Patent Application Publication
(10) Pub. No.: US 2019/0115194 A1
(43) Pub. Date: Apr. 18, 2019

(54) SUBSTRATE SUPPORTING MEMBER AND SUBSTRATE PROCESSING APPARATUS INCLUDING SAME

(71) Applicant: SEMES CO., LTD., Cheonan-si (KR)

(72) Inventor: Sang Kee LEE, Cheonan-si (KR)

(73) Assignee: SEMES CO., LTD., Cheonan-si (KR)

(21) Appl. No.: 16/160,587

(22) Filed: Oct. 15, 2018

(30) Foreign Application Priority Data
Oct. 18, 2017 (KR) 10-2017-0134982

(51) Int. Cl. H01J 37/32

(52) U.S. Cl. CPC H01J 37/32724; H01J 2237/002; H01J 37/32449

(57) ABSTRACT

The present invention relates to a substrate supporting member and a substrate processing method. A gas flow path supplying a heat transfer gas to a rear surface of a substrate is provided in the substrate supporting member according to an embodiment of the present invention. Furthermore, a gas flow restricting member restricting gas flow to a different extent from each other according to a direction of the gas flow is provided at the gas flow path or at an external heat transfer gas supply pipe connected to the gas flow path. According to the present invention, by providing the gas flow restricting member restricting the gas flow to a different extent from each other according to the direction of the gas flow, there are effects of minimizing the time required for exhausting the heat transfer gas while preventing the arcing from occurring in a heat transfer gas flow path.

### CROSS REFERENCE TO RELATED APPLICATION

The present application claims priority to Korean Patent Application No. 10-2017-0134982, filed Oct. 18, 2017, the entire contents of which is incorporated herein for all purposes by this reference.

### BACKGROUND OF THE INVENTION

### Field of the Invention

The present invention relates to a substrate supporting member provided with a heat transfer gas flow path and a substrate processing apparatus including the same.

### Description of the Related Art

In processing a substrate for fabrication of a semiconductor device or display, it is necessary to maintain the substrate uniformly at a predetermined temperature. To this end, the substrate supporting member for supporting the substrate is provided with a temperature control means such as a heater, a refrigerant path, or the like. For smooth heat transfer between the temperature control means and the substrate, a heat transfer gas flow path for supplying heat transfer gas such as helium (He) and the like to a rear surface of the substrate is generally provided on the substrate supporting member.

During the substrate processing, the substrate is allowed to be processed under a controlled temperature by supplying the heat transfer gas to the rear surface of the substrate in a state where the substrate is fixed to the substrate supporting member by using an electrostatic force or the like. Provided the substrate processing is completed, the substrate is separated from the substrate supporting member after the heat transfer gas is exhausted from the heat transfer gas flow path to prevent the substrate from being bounced by the pressure of the heat transfer gas remaining between the rear surface of the substrate and the substrate supporting member.

Meanwhile, in the case of a substrate processing apparatus using plasma for substrate processing, unwanted arcing may occur inside the heat transfer gas flow path of the substrate supporting member due to a high frequency power applied for plasma generation. In order to prevent such an occurrence of arcing, a method of minimizing a space where the arcing may occur, such as reducing the diameter of the gas flow path or disposing a porous member in the gas flow path, and the like is proposed.

However, since the conductance of the gas flow path is reduced according to this method as a result, the time required for exhausting the remaining heat transfer gas after completion of the substrate processing process is increased, thereby deteriorating the productivity.

### SUMMARY OF THE INVENTION

Accordingly, the present invention has been made keeping in mind the above problems occurring in the related art, an object of the present invention is to provide a substrate supporting member and a substrate processing apparatus including the same, which can minimize arcing in a heat transfer gas flow path for supplying heat transfer gas to a rear surface of the substrate while minimizing the time required for exhausting heat transfer gas.

In order to achieve the above object, according to one aspect of the present invention, there is provided a substrate supporting member supporting a substrate, the substrate supporting member including: a gas flow path provided at the substrate supporting member for supplying gas to a rear surface of the substrate; and a gas flow restricting member provided at the gas flow path for restricting gas flow to a different extent from each other according to a direction of the gas flow.

The gas flow is smoother in a case where the gas is exhausted from the gas flow path as compared with a case where the gas is supplied through the gas flow path, and the gas flow restricting member is movably provided at the inside of the gas flow path.

At this time, movement of the gas flow restricting member is accomplished by the gas flow inside the gas flow path, and the gas flow restricting member is movable in the direction of the gas flow inside the gas flow path.

The gas flow path includes: an accommodating portion in which the gas flow restricting member is accommodated; and an upper flow path and a lower flow path located at upper and lower portions, respectively, with the accommodating portion as a center, wherein the accommodating portion communicates with the upper flow path and the lower flow path through the upper opening and the lower opening, respectively, wherein the gas flow restricting member may be configured not to be allowed to pass through the upper opening or the lower opening.

The gas flow restricting member blocks the upper opening or the lower opening while being raised or lowered inside the accommodating portion, wherein a non-blocked section where the gas flow is not restricted is larger in a case where the lower opening is blocked as compared with a case where the upper opening is blocked, which may be due to a difference in shapes or sizes of the upper opening and the lower opening.

Furthermore, a reason why the non-blocked section is larger in a case where the gas flow restricting member blocks the lower opening as compared with a case where the gas flow restricting member blocks the upper opening may be due to a shape of the gas flow restricting member, wherein the gas flow restricting member may be asymmetrical in upper and lower shapes.

Furthermore, by forming a penetrating flow path inside the gas flow restriction member, the gas flow through the penetrating flow path may be made smoother in a case where the gas flow restricting member blocks the lower opening as compared with a case where the gas flow restricting member blocks the upper opening. Here, the penetrating flow path includes: an upper penetrating flow path; and a lower penetrating flow path, wherein the upper penetrating flow path communicates the accommodating portion with the upper flow path in a case where the gas flow limiting member blocks the upper opening, wherein the lower penetrating flow path communicates the accommodating portion with the lower flow path in a case where the gas flow limiting member blocks the lower opening, and a diameter of the lower penetrating flow path may be larger as compared with that of the upper penetrating flow path.

Furthermore, by forming a support portion protruding from the bottom surface of the gas flow restricting member, thereby separating and supporting the gas flow restricting member not to completely block the lower opening, the gas flow through a path portion may be made smoother in a case where the gas flow restricting member blocks the lower opening as compared with a case where the gas flow restricting member blocks the upper opening. Here, a path portion may be provided for preventing the accommodating portion and the lower opening from being blocked by the support portion, and the path portion is formed between the plurality of support portions. In addition, the path portion may extend to a side surface of the gas flow restricting member.

In an embodiment of the present invention, the gas flow restricting member may be a porous member.

In addition, in an embodiment of the present invention, a bushing is inserted in the gas flow path, and the accommodating portion is formed by the bushing.

In addition, in an embodiment of the present invention, the gas flow restricting member may be of a size or a shape not allowed to be turned upside down inside the accommodating portion, or an upside down movement preventing member may be provided for preventing the gas flow restricting member from being turned upside down inside the accommodating portion.

In addition, the substrate supporting member according to an embodiment of the present invention includes: a chuck member for fixing the substrate; and a base plate for supporting the chuck member, wherein the gas flow path may be formed passing through the base plate and the chuck member. Here, the gas flow path includes: a main flow path connected to a heat transfer gas supply pipe; a plurality of branch flow paths branched off from the main flow path to supply gas to the rear surface of the substrate; and a connection flow path connecting the main flow path and the branch flow paths, wherein the gas flow restricting member may be provided at least at one of the heat transfer gas supply pipe, the main flow path, the branch flow paths, and the connection flow path.

In addition, the base plate is provided with a refrigerant flow path, and the gas may be a heat transfer gas for facilitating heat transfer between the base plate and the substrate.

A substrate processing apparatus according to another aspect of the present invention includes: a chamber providing an interior space where a substrate processing process is performed; a substrate supporting member provided at the inside of the chamber and supporting a substrate; and a gas injection unit injecting a process gas to the substrate, wherein a heat transfer gas flow path is formed in the substrate supporting member for supplying and exhausting a heat transfer gas, wherein a flow rate of the heat transfer gas is larger in a case where the heat transfer gas is exhausted as compared with a case where the heat transfer gas is supplied.

Here, a gas flow restricting member may be provided for restricting the flow of the heat transfer gas to a different extent from each other in a case where the heat transfer gas is supplied or exhausted.

In addition, the substrate processing apparatus includes:

a heat transfer gas supply source for supplying the heat transfer gas; and a heat transfer gas supply pipe connecting the heat transfer gas supply source and the heat transfer gas flow path, wherein the gas flow restricting member may be provided at least at one of the heat transfer gas flow path and the heat transfer gas supply pipe.

In addition, the heat transfer gas supply pipe may be connected to a vacuum pump through an exhaust line.

In addition, the substrate processing apparatus may be a plasma processing apparatus.

According to the embodiment of the present invention, the gas flow restricting member is provided at the inside of the heat transfer gas flow path for restricting the gas flow to a different extent from each other according to the direction of the gas flow. Accordingly, there are effects of minimizing the time required for exhausting heat transfer gas while preventing the arcing from occurring inside the heat transfer gas flow path.

### BRIEF DESCRIPTION OF THE DRAWINGS

The above and other objects, features, and other advantages of the present invention will be more clearly understood from the following detailed description when taken in conjunction with the accompanying drawings, in which:

FIG. 1 is a cross-sectional view of a substrate processing apparatus according to an embodiment of the present invention.

FIG. 2 is a partial enlarged view of a substrate supporting member according to an embodiment of the present invention, illustrating a case where heat transfer gas is supplied.

FIG. 3 is a partial enlarged view of a substrate supporting member according to an embodiment of the present invention, illustrating a case where heat transfer gas is exhausted.

FIGS. 4A to 8B are views for explaining the operation of a gas flow restricting member according to embodiments of the present invention, wherein FIGS. 4A, 5A, 6A, 7A, and 8A illustrate cases where heat transfer gas is supplied, and FIGS. 4B, 5B, 6B, 7B, and 8B illustrate cases where heat transfer gas is exhausted.

FIG. 9 is a perspective view of the gas flow restricting member of the embodiment of FIGS. 8A and 8B.

### DETAILED DESCRIPTION OF THE INVENTION

Hereinbelow, the present invention will be described in detail with reference to the accompanying drawings. Throughout the drawings, the same reference numerals will refer to the same or like parts. The following description includes specific embodiments, but the present invention is not limited to or limited by the illustrated embodiments. In describing the present invention, detailed descriptions of prior arts which have been deemed to obfuscate the gist of the present invention will be omitted below.

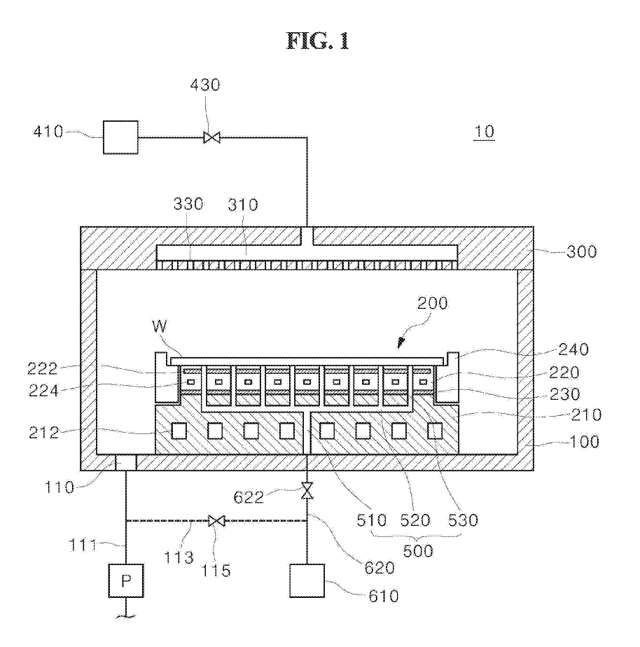

FIG. 1 is a cross-sectional view of a substrate processing apparatus according to an embodiment of the present invention.

With reference to FIG. 1, the substrate processing apparatus 10 includes a chamber 100, a substrate supporting member 200, and a gas injection unit 300.

The chamber 100 provides an interior space where the substrate processing process is performed. The substrate processing process can be performed in a vacuum atmosphere, and an exhaust port 110 is formed in the chamber 100 for this purpose. A vacuum pump P is connected to the exhaust port 110 through a main exhaust line 111.

The gas injection unit 300 is configured to inject a process gas for substrate processing onto a substrate W and includes a diffusion chamber 310 connected to the process gas source 410 and a plurality of injection holes 330. The plurality of injection holes 330 is formed on the surface facing the substrate W and ejects the process gas supplied from the process gas source 410 to the diffusion chamber 310 onto a top surface of the substrate W. A process gas supply valve 430 regulates the flow rate of the process gas supplied to the gas injection unit 300.

Inside the chamber 100, the substrate supporting member 200 is provided for supporting the substrate W. The substrate supporting member 200 may include a chuck member 220 for holding and fixing the substrate W and a base plate 210 for supporting the chuck member 220. Here, the chuck member 220 and the base plate 210 may be adhered by the bonding layer 230, wherein a bonding layer 230 may be formed by silicon and the like.

The chuck member 220 may be formed of a dielectric plate such as alumina and the like and may be provided with an electrostatic electrode 222 for generating an electrostatic force therein. When voltage is applied to the electrostatic electrode 222 by a power source (not shown), an electrostatic force is generated and the substrate W is attracted and fixed to the chuck member 220. Although the chuck member 220 is an electrostatic chuck for fixing the substrate W by an electrostatic force, the chuck member 220 may be a vacuum chuck, a mechanical clamp, or other fixing means. The chuck member 220 may be provided with a heater 224 for heating the substrate W to a predetermined temperature.

The base plate 210 is located below the chuck member 220 and may be formed of a metal material such as aluminum and the like. The base plate 210 is provided with a refrigerant flow path 212 through which a cooling fluid flows, thereby being able to function as a cooling means for cooling the chuck member 220. The refrigerant flow path 212 may be provided as a circulation path through which the cooling fluid circulates.

Meanwhile, even though the base plate 210 is cooled by the cooling fluid circulating through the refrigerant flow path 212, the substrate W may not be cooled as desired when heat transfer between the base plate 210 and the substrate W is not smooth. Accordingly, a heat transfer gas flow path 500 is formed in the substrate supporting member 200, thereby providing a heat transfer gas to the rear surface of the substrate.

The heat transfer gas flow path 500 may include a main flow path 510 connected to a heat transfer gas supply pipe 620 and a plurality of branch flow paths 530 branched off from the main flow path 510 to provide the heat transfer gas to the rear surface of the substrate W, and a connection flow path 520 for connecting the main flow path 510 and the branch flow paths 530 and for extending heat transfer gas flow in the horizontal direction. The main flow path 510 and the connection flow path 520 may be formed inside the base plate 210, and the branch flow path 530 may be formed penetrating the chuck member 220 from the connection flow path 520 to the top surface of the chuck member 220. The connection flow path 520 may be a spiral flow path starting from the connection portion with the main flow path 510 and extending in the radial direction of the substrate supporting member 200. The heat transfer gas supply pipe 620 is connected to the main exhaust line 111 through the auxiliary exhaust line 113, thereby being able to exhaust the heat transfer gas remaining in the heat transfer gas flow path 500 to the vacuum pump P by opening an exhaust valve 115. The exhaust valve 115 may be provided as a three-way valve at a connecting portion between the heat transfer gas supply pipe 620 and the auxiliary exhaust line 113.

Although not shown in FIG. 1, the substrate processing apparatus 10 may include a high-frequency power source for generating plasma. That is, the substrate processing apparatus 10 may be a plasma processing apparatus having a plasma source. Meanwhile, the plasma may be generated in various ways. For example, an inductively coupled plasma (ICP) method, a capacitively coupled plasma (CCP) method, or a remote plasma method may be used

In the case where the substrate processing apparatus 10 is a plasma processing apparatus, the substrate processing process may proceed in a state where the plasma is generated between the gas injection unit 300 and the substrate W. At this time, undesired substrate heating may occur due to the plasma. The temperature of the substrate W may be maintained at a predetermined temperature or less by supplying the heat transfer gas to the rear surface of the substrate in a state where the cooling fluid through the refrigerant flow path 212 is circulated.

The substrate processing process by the substrate processing apparatus 10 may be performed in the following order. First, the substrate W is carried into the chamber 100 and placed on the substrate supporting member 200. More specifically, the substrate W is mounted on the chuck member 220 and the voltage is applied to the electrostatic electrode 222 to generate an electrostatic force, thereby fixing the substrate W to the chuck member 220. The process gas is supplied into the chamber 100 by the gas injection unit 300 and the pressure inside the chamber 100 is adjusted to the process pressure in such a manner that the process gas flow rate and the conductance of the exhaust port 110 are adjusted. In the case of the plasma processing process, the plasma is generated by using a high frequency power source (not shown).

The heat transfer gas such as helium (He) and the like stored in the heat transfer gas supply source 610 is supplied to the main flow path 510 through the heat transfer gas supply pipe 620 by controlling the heat transfer gas supply valve 622. The heat transfer gas provided is supplied to a space between the substrate W and the chuck member 220 through the connection flow path 520 and the branch flow paths 530. Accordingly, the heat transfer between the base plate 210 whose temperature is controlled by the cooling fluid flowing through the refrigerant flow path 212 and the substrate W becomes smooth, thereby preventing the substrate W from being overheated. When the substrate processing process is completed, the heat transfer gas inside the heat transfer gas flow path 500 is exhausted by opening the exhaust valve 115. After exhausting the heat transfer gas so that the pressure inside the heat transfer gas flow path 500 is sufficiently lowered, the electrostatic force applied to the substrate W is removed. Subsequently, the substrate W is separated from the chuck member 220 and is taken out of the chamber 100.

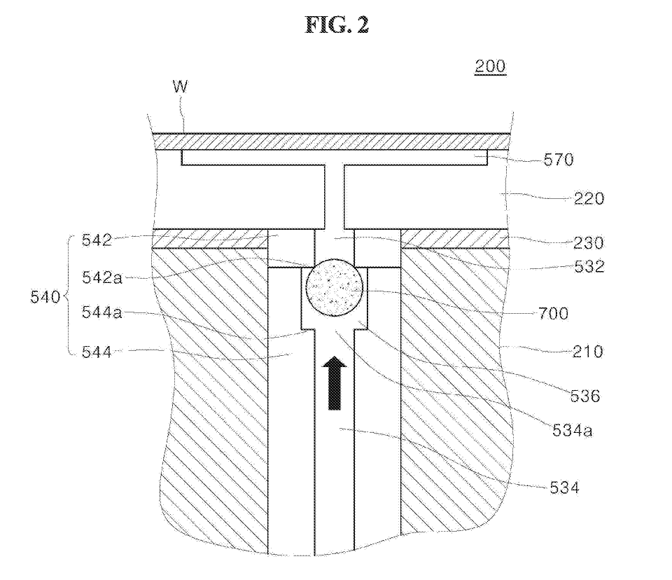

Meanwhile, in the case where the heat transfer gas flow path 500 is miniaturized or the porous member is disposed to prevent arcing from occurring inside the heat transfer gas flow path 500, there is a problem that it takes a long time to exhaust the heat transfer gas after completion of the substrate processing process. In order to solve this problem, the present invention is characterized in that a gas flow restricting member 700 is provided at the inside of the heat transfer gas flow path 500, whereby relatively smoother gas flow is achieved in the case where the heat transfer gas is exhausted as compared with the case where the heat transfer gas is supplied. In the description with reference to FIGS. 2 to 7B, it is described that the gas flow restricting member 700 is provided at the branch flow path 530, but the present invention is not limited thereto. That is, the gas flow restricting member 700 may be provided at the main flow path 510 or the connection flow path 520, or may be provided at the heat transfer gas supply pipe 620.

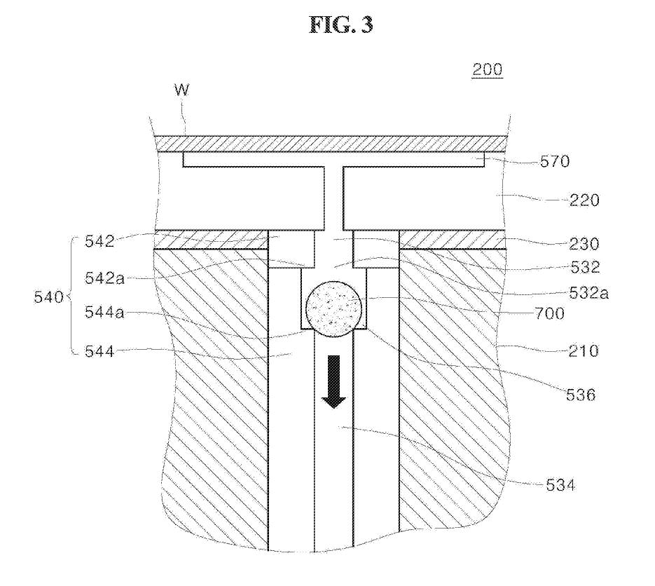

FIGS. 2 and 3 are partial enlarged views of the substrate supporting member 200 according to an embodiment of the present invention. With reference to FIGS. 2 and 3, the gas flow restricting member 700 is provided at the inside of the heat transfer gas flow path 500. The gas flow restricting member 700 may be formed of a porous material, thereby allowing the heat transfer gas to pass through the fine pores therein.

The gas flow restricting member 700 may be disposed in an accommodating portion 536 provided at the inside of the heat transfer gas flow path 500, thereby being allowed to move by the gas flow. The accommodating portion 536 may be provided by a bushing 540 inserted inside the branch flow path 530. The bushing 540 includes an upper bushing 542 and a lower bushing 544, and the accommodating portion 536 may be a space between an upper stepped portion 542a and a lower stepped portion 544a. The gas flow restricting member 700 may be configured to be allowed to move only within the accommodating portion 536 by being caught by the upper stepped portion 542a or the lower stepped portion 544a, thereby not being allowed to move upward through an upper opening 532a or to move downward through a lower opening 534a. The bushing 540 may be formed of an insulating material or a metallic material coated with an insulating layer. In an exemplary embodiment, the gas flow restricting member 700 may be a freestanding element that is accommodated within the accommodating portion 536, thereby the gas flow restricting member 700 being movable inside the accommodating portion 536 by the gas flow flowing therethrough.

The heat transfer gas supplied to the heat transfer gas flow path 500 passes in order through a lower flow path 534, the accommodating portion 536, and an upper flow path 532, thereby being provided to the space between the chuck member 220 and the substrate W. A groove portion 570 may be formed on the top surface of the chuck member 220. Here, the groove portion 570 may be formed in a spiral shape, thereby allowing the heat transfer gas to be provided entirely on the rear surface of the substrate.

In an exemplary embodiment, the lower flow path 534 includes the lower opening 534a and is connected to the accommodating portion 536 through the lower opening 534a.

In an exemplary embodiment, the upper flow path 532 includes the upper opening 532a and is connected to the accommodating portion 536 through the upper opening 532a.

FIG. 2 illustrates the case where the heat transfer gas is supplied toward the rear surface of the substrate. The gas flow restricting member 700 is raised by the flow of the heat transfer gas and is brought into close contact with the upper stepped portion 542a. FIG. 3 illustrates the case where the heat transfer gas is exhausted. At this time, since the gas flow in the opposite direction to the gas flow of FIG. 2 is generated, the gas flow restricting member 700 is lowered and brought into close contact with the lower stepped portion 544a.

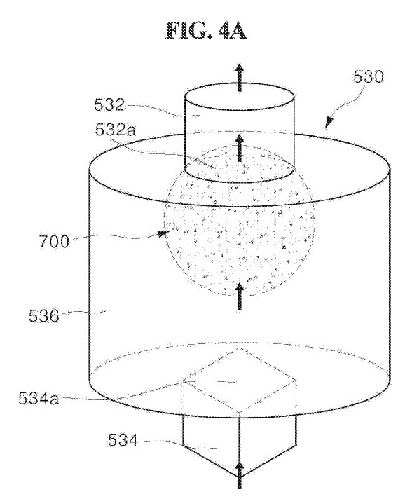

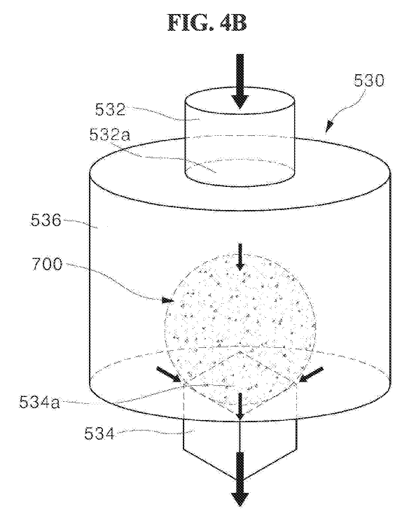

In the present invention, the relatively smooth gas flow is achieved in the case of FIG. 3 where the heat transfer gas is exhausted as compared with the case of FIG. 2 where the heat transfer gas is supplied. This can be materialized by using various methods such as adjusting shape and structure of the gas flow restricting member 700, shape of the upper opening 532a and shape of the lower opening 534a. This will be described below with reference to FIGS. 4A to 8B. FIGS. 4A to 8B illustrate only the upper and lower flow paths 532 and 534, respectively, and the accommodating portion 536 therebetween and the gas flow restricting member 700 accommodated inside the accommodating portion 536. Meanwhile, FIGS. 4A to 8B are conceptual diagrams for explaining the principle that the conductance and the flow rate of the heat transfer gas of the heat transfer gas flow path 500 differ according to the direction of the heat transfer gas flow. At this time, the accommodating portion 536 is assumed to be a cylindrical shape.

FIGS. 4A and 4B illustrate an embodiment in which the shapes of the upper flow path 532 and the lower flow path 534 are configured differently and, more specifically, the shapes of the upper opening 532a and the lower opening 534a are configured differently. Accordingly, the relatively smooth gas flow can be achieved in the case where the heat transfer gas is exhausted as compared with the case where the heat transfer gas is supplied. With reference to FIGS. 4A and 4B, the upper flow path 532 is formed in a cylindrical shape and the lower flow path 534 is formed in a square pillar shape, whereby the upper opening 532a and the lower opening 534a are circular and rectangular, respectively. The gas flow restricting member 700 is accommodated inside the cylindrical accommodating portion 536 in such a manner that it can be vertically moved along the direction of the gas flow and is configured in a size that cannot pass through the upper opening 532a and the lower opening 534a. In the present embodiment, the gas flow restricting member 700 may be a spherical porous member.

FIG. 4A illustrates a case where the heat transfer gas is supplied toward the rear surface of the substrate. The gas flow restricting member 700 accommodated in the accommodating portion 536 is raised in accordance with the flow of the heat transfer gas and is caught by the upper stepped portion 542a, whereby the movement thereof is restricted. By the spherical gas flow restricting member 700, the upper opening 532a can be completely blocked. In this state, the heat transfer gas passing through the lower flow path 534 and the accommodating portion 536 can be supplied to the upper flow path 532 only through the inner pores of the porous gas flow restricting member 700.

FIG. 4B illustrates a case where the heat transfer gas is exhausted from the rear surface of the substrate. The gas flow restricting member 700 accommodated in the accommodating portion 536 is lowered in accordance with the flow of the heat transfer gas and is caught by the lower stepped portion 544a, whereby the movement thereof is restricted. By the spherical gas flow restricting member 700, the upper opening 532a can be blocked. However, since the lower opening 534a is formed in the square shape, it is not completely blocked by the spherical gas flow restricting member 700. Accordingly, the heat transfer gas can be exhausted through the vertex portions of the square. That is, the heat transfer gas that has passed through the upper flow path 532 and the accommodating portion 536 can be exhausted to the lower flow path 534 not only through the inner pores of the porous gas flow restricting member 700, but also through the vertex portions (non-blocked section) of the lower opening 534a.

According to the embodiment of FIGS. 4A and 4B above, the conductance of the heat transfer gas flow path 500 can be made to become larger in the case where the heat transfer gas is exhausted after the substrate processing process is completed as compared with the case where the heat transfer gas is supplied toward the rear surface of the substrate during the substrate processing process. Accordingly, it is possible to exhaust the heat transfer gas at a relatively high speed.

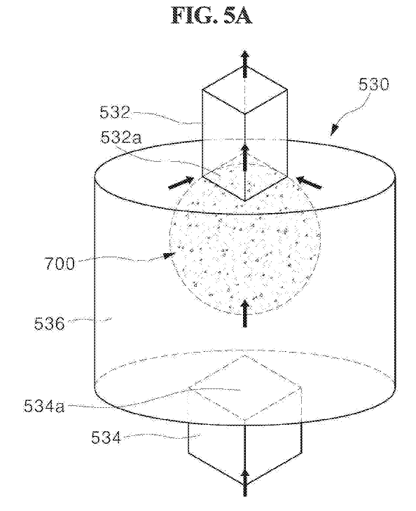

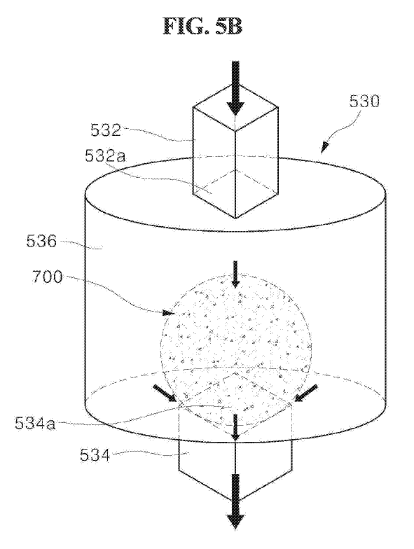

FIGS. 5A and 5B illustrate an embodiment, in which the sizes of the upper opening 532a and the lower opening 534a are different from each other, thereby allowing a relatively smoother gas flow to be achieved in the case where the heat transfer gas is exhausted as compared with the case where the heat transfer gas is supplied. With reference to FIGS. 5A and 5B, both the upper opening 532a and the lower opening 534a are square, but the lower opening 534a is formed in a square shape of a larger size than the upper opening 532a. The gas flow restricting member 700 is accommodated inside the cylindrical accommodating portion 536 in such a manner that it can be vertically moved along the direction of the gas flow and is configured in a size that cannot pass through the upper opening 532a or the lower opening 534a. In the present embodiment, the gas flow restricting member 700 may be a spherical porous member, but is not limited to a porous member.

FIG. 5A illustrates a case where a heat transfer gas is supplied toward the rear surface of the substrate. The gas flow restricting member 700 accommodated in the accommodating portion 536 is raised in accordance with the flow of the heat transfer gas and is caught by the upper stepped portion 542a, whereby the movement thereof is restricted. By the spherical gas flow restricting member 700, the upper opening 532a may be blocked. However, since the upper opening 532a is formed in the square, it is not completely blocked by the spherical gas flow restricting member 700, and the heat transfer gas can be supplied through the non-blocked section of the vertex portions of the square. That is, the heat transfer gas that has passed through the lower flow path 534 and the accommodating portion 536 is supplied to the upper flow path 532 through the vertex portions of the upper opening 532a. In addition, when the gas flow restricting member 700 is the porous member, the heat transfer gas can also be supplied to the upper flow path 532 passing through the inner pores of the porous gas flow restricting member 700.

FIG. 5B illustrates a case where the heat transfer gas is exhausted from the rear surface of the substrate. The gas flow restricting member 700 accommodated in the accommodating portion 536 is lowered in accordance with the flow of the heat transfer gas, and is caught by the lower stepped portion 544a, whereby the movement thereof is restricted. By the spherical gas flow restricting member 700, the upper opening 534a may be blocked. Since the lower opening 534a has a square shape, it is not completely blocked by the spherical gas flow restricting member 700, and the heat transfer gas can be exhausted through the non-blocked section of the square vertex portion. That is, the heat transfer gas that has passed through the upper flow path 532 and the accommodating portion 536 is exhausted to the lower flow path 534 through the vertex portions of the lower opening 534a. In addition, when the gas flow restricting member 700 is the porous member, the heat transfer gas can also be exhausted to the lower flow path 534 passing through the inner pores of the porous gas flow restricting member 700.

Since the lower opening 534a is formed in a square shape of a larger size as compared with the upper opening 532a, the area of the non-blocked section of the vertex portion in the state where the gas flow restricting member 700 blocks the gas flow differs. That is, the conductance of the heat transfer gas flow path 500 can be further increased in the case where the heat transfer gas is exhausted in a state that the lower opening 534a is blocked by the gas flow restricting member 700 as compared with the case where the heat transfer gas is supplied in a state that the upper opening 532a is blocked by the gas flow restricting member 700. Accordingly, it is possible to exhaust the heat transfer gas at a relatively high speed.

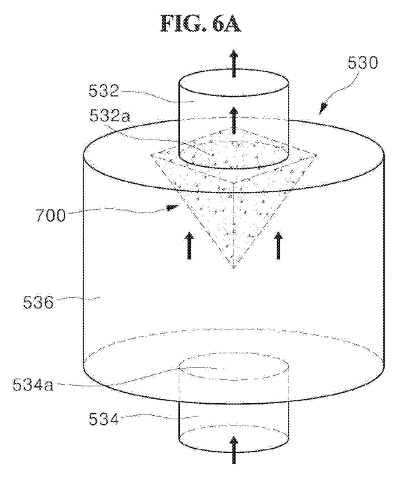

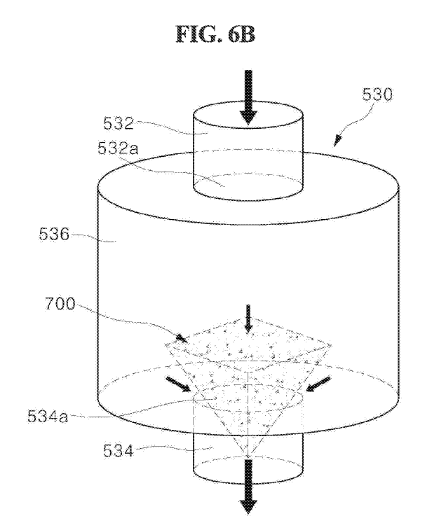

FIGS. 6A and 6B illustrate an embodiment in which the shape of the gas flow restricting member 700 is adjusted, thereby allowing a relatively smoother gas flow to be achieved in the case where the heat transfer gas is exhausted as compared with the case where the heat transfer gas is supplied. With reference to FIGS. 6A and 6B, the upper opening 532a and the lower opening 534a are both circular and may be the same size. The gas flow restricting member 700 is accommodated inside the cylindrical accommodating portion 536 in such a manner that it can be vertically moved along the direction of the gas flow and is configured in a size that cannot pass through the upper opening 532a or the lower opening 534a. In the present embodiment, the gas flow restricting member 700 may be a porous member.

In the present embodiment, the gas flow restricting member 700 is configured to have upper and lower shapes formed asymmetrically in the vertical direction. For example, the gas flow restricting member 700 may have a quadrangular pyramid shape inverted to have a bottom surface in the direction of the upper flow path 532. At this time, the bottom surface of the quadrangular pyramid may be of a size that can entirely cover the upper opening 532a.

FIG. 6A illustrates a case where the heat transfer gas is supplied toward the rear surface of the substrate. The gas flow restricting member 700 accommodated in the accommodating portion 536 is raised in accordance with the flow of the heat transfer gas and is caught by the upper stepped portion 542a, whereby the movement thereof is restricted. By the bottom surface of the quadrangular pyramid, the upper opening 532a can be completely blocked. In this state, the heat transfer gas passing through the lower flow path 534 and the accommodating portion 536 can be supplied to the upper flow path 532 only through the inner pores of the porous gas flow restricting member 700.

FIG. 6B illustrates a case where the heat transfer gas is exhausted from the rear surface of the substrate. The gas flow restricting member 700 accommodated in the accommodating portion 536 is lowered in accordance with the flow of the heat transfer gas, and is caught by the lower stepped portion 544a, whereby the movement thereof is restricted. By the gas flow restricting member 700, the lower opening 534a can be blocked. However, since the gas flow restricting member 700 is formed in the shape of the quadrangular pyramid, the lower opening 534a is not completely blocked by the gas flow restricting member 700, and the heat transfer gas can be exhausted through open spaces between the side surface portions of the quadrangular pyramid and the lower stepped portion 544a. That is, the heat transfer gas that has passed through the upper flow path 532 and the accommodating portion 536 can be exhausted to the lower flow path 534 not only through the inner pores of the porous gas flow restricting member 700, but also through the open region (non-blocked section) of the lower opening 534a.

According to the embodiment of FIGS. 6A and 6B above, the conductance of the heat transfer gas flow path 500 can be made to become larger in the case where the heat transfer gas is exhausted after the substrate processing process is completed as compared with the case where the heat transfer gas is supplied toward the rear surface of the substrate during the substrate processing process. Accordingly, it is possible to exhaust the heat transfer gas at a relatively high speed.

Since it is important for the gas flow restricting member 700 to be maintained straight in the vertical direction, it is preferable that the gas flow restricting member 700 is formed to have a size such that the gas flow restricting member 700 is not to be positioned upside down by a rotation thereof inside the accommodating portion 536.

Otherwise, a separate upside down movement preventing member (not shown) may be provided. For example, the gas flow restricting member 700 may be connected to the wall surface of the accommodating portion 536 by a spring, whereby upside down movement is not allowed while up and down movement is permitted for the gas flow restricting member 700. Alternatively, a protruding member may be formed in the middle of the height of the accommodating portion 536 to prevent the gas flow restricting member 700 from being rotated.

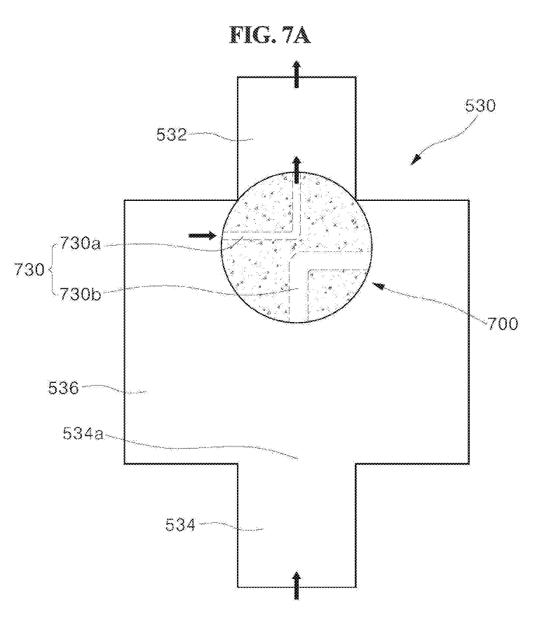

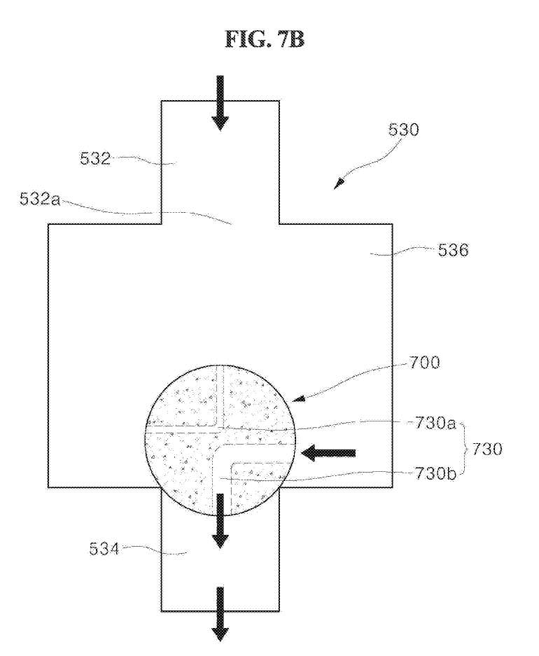

FIGS. 7A and 7B illustrate an embodiment, in which the shape of the gas flow restricting member 700 is adjusted, thereby allowing a relatively smoother gas flow to be achieved in the case where the heat transfer gas is exhausted as compared with the case where the heat transfer gas is supplied. FIGS. 7A and 7B are cross-sectional views for explaining the upper and lower flow paths 532 and 534, respectively, the accommodating portion 536, and the gas flow restricting member 700.

With reference to FIGS. 7A and 7B, the upper opening 532a and the lower opening 534a are both circular and may be the same size. The gas flow restricting member 700 is accommodated inside the cylindrical accommodating portion 536 in such a manner that it can be vertically moved along the direction of the gas flow and is configured in a size that cannot pass through the upper opening 532a or the lower opening 534a.

The gas flow restricting member 700 in the present embodiment has a penetrating flow path 730 formed therein. The penetrating flow path 730 includes an upper penetrating flow path 730a and a lower penetrating flow path 730b.

The upper penetrating flow path 730a is a flow path through which the both ends of the flow path are opened to the accommodating portion 536 and the upper flow path 532, respectively, so that the accommodating portion 536 and the upper flow path 532 communicate with each other, when the gas flow restricting member 700 is in close contact with the upper stepped portion 542a. In addition, the lower penetrating flow path 730b is a flow path through which the both ends of the flow path are opened to the accommodating portion 536 and the lower flow path 534, respectively, so that the accommodating portion 536 and the lower flow path 534 communicate with each other, when the gas flow restricting member 700 is in close contact with the lower stepped portion 544a. At this time, the lower penetrating flow path 730b is formed to have a larger diameter as compared with the upper penetrating flow path 730a.

Although the gas flow restricting member 700 is illustrated as a spherical shape in the drawing, it can be changed into various shapes such as a cylindrical shape, a rectangular parallelepiped shape, or the like. In addition, the gas flow restricting member 700 may be a porous member, but is not limited thereto.

FIG. 7A illustrates a case where a heat transfer gas is supplied toward the rear surface of the substrate. The gas flow restricting member 700 accommodated in the accommodating portion 536 is raised in accordance with the flow of the heat transfer gas and is caught by the upper stepped portion 542a, whereby the movement thereof is restricted. By the spherical gas flow restricting member 700, the upper opening 532a may be blocked. However, since the accommodating portion 536 and the upper flow path 532 communicate with each other by the upper penetrating flow path 730a, the upper opening 532a is not completely blocked by the gas flow restricting member 700. That is, the heat transfer gas that has passed through the lower flow path 534 and the accommodating portion 536 is supplied to the upper flow path 532 through the upper penetrating flow path 730a. In addition, when the gas flow restricting member 700 is the porous member, the heat transfer gas can also be supplied to the upper flow path 532 passing through the inner pores of the porous gas flow restricting member 700.

FIG. 7B illustrates a case where the heat transfer gas is exhausted from the rear surface of the substrate. The gas flow restricting member 700 accommodated in the accommodating portion 536 is lowered in accordance with the flow of the heat transfer gas and is caught by the lower stepped portion 544a, whereby the movement thereof is restricted. By the spherical gas flow restricting member 700, the lower opening 534a may be blocked. However, since the accommodating portion 536 and the lower flow path 534 communicate with each other by the lower penetrating flow path 730b, the lower opening 534a is not completely blocked by the gas flow restricting member 700. That is, the heat transfer gas that has passed through the upper flow path 532 and the accommodating portion 536 is exhausted to the lower flow path 534 through the lower penetrating flow path 730b. In addition, when the gas flow restricting member 700 is the porous member, the heat transfer gas can also be exhausted to the lower flow path 534 passing through the inner pores of the porous gas flow restricting member 700.

Here, since the lower penetrating flow path 730b is formed to have a larger diameter as compared with the upper penetrating flow path 730a, the degree of blocking the gas flow in the state where the gas flow restricting member 700 blocks the gas flow differs. That is, the conductance of the heat transfer gas flow path 500 can be further increased in the case where the heat transfer gas is exhausted in a state that the lower opening 534a is blocked by the gas flow restricting member 700 as compared with the case where the heat transfer gas is supplied in a state that the upper opening 532a is blocked by the gas flow restricting member 700. Accordingly, it is possible to exhaust the heat transfer gas at a relatively high speed.

In FIGS. 7A and 7B, the gas flow restricting member 700 is illustrated as a spherical shape. However, the gas flow restricting member 700 may be configured into a different shape such as a cylindrical shape, a hexahedron shape, or the like with a size to the extent impossible to be turned upside down in order to prevent the gas flow restricting member 700 from being rotated and being turned upside down inside the accommodating portion 536. Otherwise, a separate upside down movement preventing member (not shown) may be provided. For example, the gas flow restricting member 700 may be connected to the wall surface of the accommodating portion 536 by a spring, whereby upside down movement is not allowed while up and down movement is permitted for the gas flow restricting member 700.

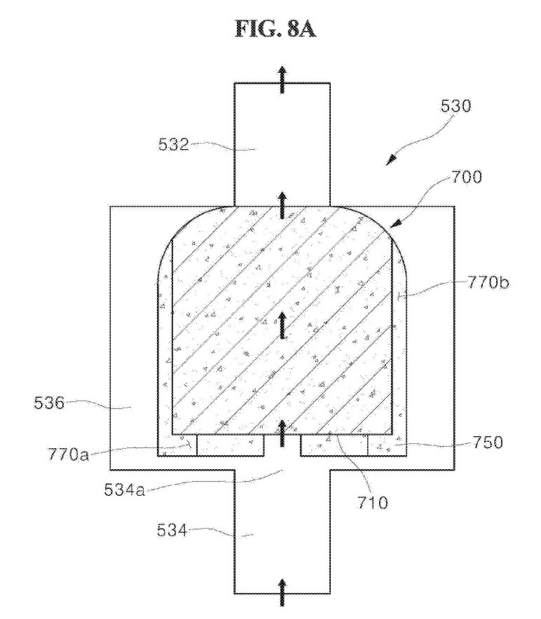

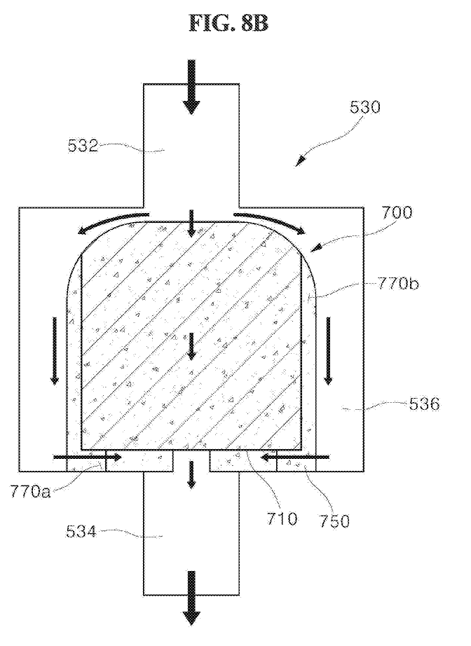

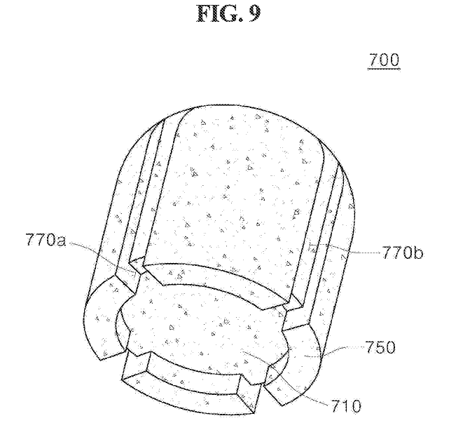

FIGS. 8A, 8B, and 9 illustrate another different embodiment, wherein FIGS. 8A and 8B illustrate cross-sectional views for explaining the upper and lower flow paths 532 and 534, respectively, the accommodating portion 536, and the gas flow restricting member 700, and FIG. 9 is a perspective view of the gas flow restricting member 700.

With reference to FIGS. 8A, 8B, and 9 together, the upper opening 532a and the lower opening 534a are both circular and may be the same size. The gas flow restricting member 700 is accommodated inside the cylindrical accommodating portion 536 in such a manner that it can be vertically moved along the direction of the gas flow and is configured in a size that cannot pass through the upper opening 532a or the lower opening 534a.

In the present embodiment, the gas flow restricting member 700 includes a support portion 750 for supporting the bottom surface 710 of the gas flow restricting member 700 to be spaced apart from and not to be brought into close contact with the lower stepped portion 544a. In addition, the support portion 750 is configured so that the path to the lower opening 534a is not blocked. For example, as illustrated in FIG. 9, a plurality of support portions 750 may be configured protruding from the bottom surface 710, and a path portion 770a may be formed between adjacent support portions 750. A path portion 770b extending from the path portion 770a is formed on the side surface of the gas flow restricting member 700 so that the gas flow from the upper portion can be guided to the path portion 770a.

The gas flow restricting member 700 may be configured generally in a cylindrical shape and may have a flat top surface such that the upper opening 532a is sealed when the gas flow restricting member 700 is in close contact with the upper stepped portion 542a. However, the edge portion of the top surface may be formed as a curved surface for smooth gas flow. The gas flow restricting member 700 is not limited to a cylindrical shape and can be changed into various shapes such as a rectangular parallelepiped and the like. In the present embodiment, the gas flow restricting member 700 may be a porous member.

FIG. 8A illustrates a case where a heat transfer gas is supplied toward the rear surface of the substrate. The gas flow restricting member 700 accommodated in the accommodating portion 536 is raised in accordance with the flow of the heat transfer gas and is caught by the upper stepped portion 542a, whereby the movement thereof is restricted. By the top surface of the gas flow restricting member 700, the upper opening 532a can be completely blocked. In this state, the heat transfer gas passing through the lower flow path 534 and the accommodating portion 536 can be supplied to the upper flow path 532 only through the inner pores of the porous gas flow restricting member 700.

FIG. 8B illustrates a case where the heat transfer gas is exhausted from the rear surface of the substrate. The gas flow restricting member 700 accommodated in the accommodating portion 536 is lowered in accordance with the flow of the heat transfer gas and is caught by the lower stepped portion 544a, whereby the movement thereof is restricted. By the gas flow restricting member 700, the lower opening 534a can be blocked. However, since the bottom surface 710 of the gas flow restricting member 700 is spaced apart from and is not brought into close contact with the lower stepped portion 544a by the support portion 750, the lower opening 534a is not completely blocked. That is, the heat transfer gas that has passed through the upper flow path 532 and the accommodating portion 536 can be exhausted to the lower flow path 534 through the path part 770a as well as the inner pores of the porous gas flow restricting member 700.

According to an embodiment of FIGS. 8A, 8B, and 9 above, the conductance of the heat transfer gas flow path 500 can be made to become larger in the case where the heat transfer gas is exhausted after the substrate processing process is completed as compared with the case where the heat transfer gas is supplied toward the rear surface of the substrate during the substrate processing process. Accordingly, it is possible to exhaust the heat transfer gas at a relatively high speed.

According to the embodiments described above, the conductance of the heat transfer gas flow path 500 can be made larger in the case where the heat transfer gas is exhausted after the substrate processing process is completed as compared with the case where the heat transfer gas is supplied toward the rear surface of the substrate during the substrate processing process. Accordingly, it is possible to prevent the arcing from occurring inside the heat transfer gas flow path 500, and to minimize the time required for exhausting the heat transfer gas, thereby improving productivity.

While the present invention has been described with reference to specific embodiments and accompanying drawings, it will be understood by those skilled in the art that various changes and modifications may be made without departing from the spirit and scope of the invention.

For example, although the gas flow restricting member is illustrated as being provided at the branch flow path in the embodiment, the gas flow restricting member may be provided at least at one of paths for supplying and exhausting the heat transfer gas, such as the branch flow paths, a main flow path, a connection flow path, a heat transfer gas supply pipe, and the like. For example, when the gas flow restricting member is installed in the main flow path, there is an advantage that only one gas flow restricting member may need to be installed. However, when the gas flow restricting member is installed in each of the plurality of branch flow paths, the object of the present invention may be achieved even if some gas flow restricting members are not operated properly. In addition, the gas flow restricting member may be provided at a plurality of positions in the heat transfer gas flow path. Further, the gas flow restricting member may be provided at the chuck member as well as the base plate.

Each of the embodiments described in the present invention may be implemented in combination of all or a part thereof selectively. For example, the penetrating flow path may be formed in the gas flow restricting member while different shapes and sizes of the upper and lower openings are provided. Accordingly, the scope of protection of the present invention should be determined by the description of the claims and equivalents thereof.

<Description of the Reference Numerals in the Drawings>

| | |
|---|---|
| 10: Substrate processing apparatus | 100: Chamber |
| 110: Exhaust port | 111: Main exhaust line |
| 113: Auxiliary exhaust line | 115: Exhaust valve |
| 200: Substrate supporting member | 210: Base plate |
| 212: Refrigerant flow path | 220: Chuck member |
| 222: Electrostatic electrode | 224: Heater |
| 230: Bonding layer | 240: Focus ring |
| 300: Gas injection unit | 310: Diffusion chamber |
| 330: Injection hole | 410: Process gas source |
| 430: Process gas supply valve | |
| 500: Heat transfer gas flow path | |
| 510: Main flow path | 520: Connection flow path |
| 530: Branch flow path | 532: Upper flow path |
| 532a: Upper opening | 534: Lower flow path |
| 534a: Lower opening | 536: Accommodating portion |
| 540: Bushing | 542: Upper bushing |
| 542a: Upper stepped portion | 544: Lower bushing |
| 544a: Lower stepped portion | |
| 610: Heat transfer gas source | |
| 620: Heat transfer gas supply pipe | |
| 622: Heat transfer gas supply valve | |
| 700: Gas flow restricting member | 730: Penetrating flow path |
| 730a: Upper penetrating flow path | |
| 730b: Lower penetrating flow path | |
| 750: Support portion | 770a, 770b: Path portion |

What is claimed is:

1. A substrate supporting member supporting a substrate, the substrate supporting member comprising:
a gas flow path provided at the substrate supporting member for supplying gas to a rear surface of the substrate; and
a gas flow restricting member provided at the gas flow path for restricting gas flow to a different extent from each other according to a direction of the gas flow.

2. The substrate supporting member of claim 1, wherein the gas flow is smoother in a case where the gas is exhausted from the gas flow path as compared with a case where the gas is supplied through the gas flow path.

3. The substrate supporting member of claim 2, wherein the gas flow restricting member is movably provided at the inside of the gas flow path.

4. The substrate supporting member of claim 3, wherein the gas flow restricting member is moved by the gas flow inside the gas flow path.

5. The substrate supporting member of claim 4, wherein the gas flow restricting member is moved in the direction of the gas flow inside the gas flow path.

6. The substrate supporting member of claim 5, wherein the gas flow path includes:
an accommodating portion in which the gas flow restricting member is accommodated; and
an upper flow path having an upper opening and a lower flow path having a lower opening located at upper and lower portions, respectively, with the accommodating portion as a center, wherein the accommodating portion communicates with the upper flow path and the lower flow path through the upper opening and the lower opening, respectively,
wherein the gas flow restricting member is not allowed to pass through the upper opening or the lower opening.

7. The substrate supporting member of claim 6, wherein the gas flow restricting member blocks the upper opening or the lower opening while being raised or lowered inside the accommodating portion, wherein a non-blocked section where the gas flow is not restricted is larger in a case where the lower opening is blocked as compared with a case where the upper opening is blocked.

8. The substrate supporting member of claim 7, wherein the non-blocked section is larger in a case where the gas flow restricting member blocks the lower opening as compared with a case where the gas flow restricting member blocks the upper opening, which is due to a difference in shapes of the upper opening and the lower opening.

9. The substrate supporting member of claim 7, wherein the non-blocked section is larger in a case where the gas flow restricting member blocks the lower opening as compared with a case where the gas flow restricting member blocks the upper opening, which is due to a difference in sizes of the upper opening and the lower opening.

10. The substrate supporting member of claim 7, wherein the non-blocked section is larger in a case where the gas flow restricting member blocks the lower opening as compared with a case where the gas flow restricting member blocks the upper opening, which is due to a shape of the gas flow restricting member.

11. The substrate supporting member of claim 10, wherein the gas flow restricting member is asymmetrical in upper and lower shapes.

12. The substrate supporting member of claim 7, wherein a penetrating flow path is formed inside the gas flow restricting member, wherein the gas flow through the penetrating flow path is smoother in a case where the gas flow restricting member blocks the lower opening as compared with a case where the gas flow restricting member blocks the upper opening.

13. The substrate supporting member of claim 12, wherein the penetrating flow path includes: an upper penetrating flow path; and a lower penetrating flow path, wherein the upper penetrating flow path communicates the accommodating portion with the upper flow path in a case where the gas flow limiting member blocks the upper opening, wherein the lower penetrating flow path communicates the accommodating portion with the lower flow path in a case where the gas flow limiting member blocks the lower opening, and a diameter of the lower penetrating flow path is larger as compared with that of the upper penetrating flow path.

14. The substrate supporting member of claim 7, wherein the gas flow restricting member is provided with a support portion, wherein the support portion is formed protruding from a bottom surface of the gas flow restricting member, thereby separating and supporting the gas flow restricting member not to completely block the lower opening.

15. The substrate supporting member of claim 14, wherein a path portion is provided for preventing the accommodating portion and the lower opening from being blocked by the support portion.

16. The substrate supporting member of claim 15, wherein a plurality of support portions is provided, wherein the path portion is formed between the plurality of support portions.

17. The substrate supporting member of claim 16, wherein the path portion extends to a side surface of the gas flow restricting member.

18. The substrate supporting member of claim 1, wherein the gas flow restricting member is a porous member.

19. The substrate supporting member of claim 6, wherein a bushing is inserted in the gas flow path, and the accommodating portion is formed by the bushing.

20. The substrate supporting member of claim 6, wherein the gas flow restricting member is of a size or a shape not allowed to be turned upside down inside the accommodating portion.

21. The substrate supporting member of claim 6, wherein an upside down movement preventing member is provided for preventing the gas flow restricting member from being turned upside down inside the accommodating portion.

22. The substrate supporting member of claim 1, further comprising:
a chuck member for fixing the substrate; and a base plate for supporting the chuck member, wherein the gas flow path is formed passing through the base plate and the chuck member.

23. The substrate supporting member of claim 22, wherein the gas flow path includes:
a main flow path connected to a heat transfer gas supply pipe;
a plurality of branch flow paths branched off from the main flow path to supply gas to the rear surface of the substrate; and
a connection flow path connecting the main flow path and the branch flow paths,
wherein the gas flow restricting member is provided at least at one of the heat transfer gas supply pipe, the main flow path, the branch flow paths, and the connection flow path.

24. The substrate supporting member of claim 22, wherein the base plate is provided with a refrigerant flow path, wherein the gas is a heat transfer gas for facilitating heat transfer between the base plate and the substrate.

25. A substrate processing apparatus, comprising:
a chamber providing an interior space where a substrate processing process is performed;
a substrate supporting member provided at the inside of the chamber and supporting a substrate; and
a gas injection unit injecting a process gas to the substrate, wherein a heat transfer gas flow path is formed in the substrate supporting member for supplying and exhausting a heat transfer gas,
wherein a flow rate of the heat transfer gas is larger in a case where the heat transfer gas is exhausted as compared with a case where the heat transfer gas is supplied.

26. The substrate processing apparatus of claim 25, wherein a gas flow restricting member is provided for restricting flow of the heat transfer gas to a different extent from each other in a case where the heat transfer gas is supplied or exhausted.

27. The substrate processing apparatus of claim 26, further comprising:
a heat transfer gas supply source for supplying the heat transfer gas; and
a heat transfer gas supply pipe connecting the heat transfer gas supply source and the heat transfer gas flow path, wherein the gas flow restricting member is provided at least at one of the heat transfer gas flow path and the heat transfer gas supply pipe.

28. The substrate processing apparatus of claim 27, wherein the heat transfer gas supply pipe is connected to a vacuum pump through an exhaust line.

29. The substrate processing apparatus of claim 27, further comprising:
an accommodating portion in which the gas flow restricting member is accommodated; and
an upper flow path having an upper opening and a lower flow path having a lower opening located at upper and lower portions, respectively, with the accommodating portion as a center, wherein the accommodating portion communicates with the upper flow path and the lower flow path through the upper opening and the lower opening, respectively,
wherein the gas flow restricting member is movable inside the accommodating portion by the flow of the heat transfer gas.

30. The substrate processing apparatus of claim 29, wherein the gas flow restricting member blocks the upper opening or the lower opening while being moved inside the accommodating portion, wherein a non-blocked section where the gas flow is not restricted is larger in a case where the lower opening is blocked as compared with the case where the upper opening is blocked.

31. The substrate processing apparatus of claim 25, wherein the substrate processing apparatus is a plasma processing apparatus.
